(19) United States
(12) Patent Application Publication
(10) Pub. No.: US 2026/0250204 A1
(43) Pub. Date: Aug. 27, 2026

(54) High-Entropy Alloy Sulfide/Two-Dimensional Nano Composite Material, Preparation Method Therefor, and Application Thereof

(71) Applicant: C-STAR (GUANGZHOU) NANO MATERIALS CO., LTD, Guangzhou, Guangdong (CN)

(72) Inventors: Haihua Shen, Guangzhou, Guangdong (CN); Gongchang Zeng, Guangzhou, Guangdong (CN); Heping Zeng, Guangzhou, Guangdong (CN)

(21) Appl. No.: 18/714,200

(22) PCT Filed: Apr. 7, 2023
(86) PCT No.: PCT/CN2023/086946

§ 371 Date: May 29, 2024

(30) Foreign Application Priority Data
Apr. 12, 2022 (CN) 202210383624.0

(51) Int. Cl. C04B 35/547; C04B 35/626; H05K 9/00

(52) U.S. Cl. CPC C04B 35/547; C04B 35/6264; C04B 35/62655; C04B 35/62675; C04B 2235/3843; C04B 2235/446; C04B 2235/449; H05K 9/0081

(57) ABSTRACT

The present application discloses a high-entropy alloy sulfide/two-dimensional nano composite material, a preparation method therefor, and an application thereof. According to the present application, zinc acetate, copper acetate, ferric acetate, nickel acetate, and cadmium acetate are dissolved in an organic solvent, then a sulfide and a two-dimensional nano material are added, dispersed, and uniformly mixed for reaction, and the high-entropy alloy sulfide/two-dimensional nano composite material is prepared in situ in one step. According to the present application, tests show that a nano high-entropy alloy sulfide has an electromagnetic wave absorption effect in a wave band of 6-18 GHz, and after the nano high-entropy alloy sulfide is compounded with the two-dimensional nano material, the wave band of the electromagnetic wave absorption effect is expanded to 5-18 GHz, and the electromagnetic wave absorption capability is improved.

This application is based on and claims priority of the Chinese Patent Application No. 202210383624.0, filed on Apr. 12, 2022, which is incorporated herein by reference in its entirety.

### TECHNICAL FIELD

The present application relates to the technical fields of electromagnetic wave absorbing material technologies, new energy electrode materials, and electro-catalysis fields, and more particularly, to a high-entropy alloy sulfide/two-dimensional nano composite material, a preparation method therefor, and an application thereof.

### BACKGROUND ART

With the progress of electronic science and technology and the continuous development of various application needs, wave absorbing materials are also developing in the direction of multi-functional composites while wave absorption performances (i.e., high performance) of the wave absorbing materials are improved. For example, in response to higher requirements for the development of anti-stealth technologies, the development of multi-spectrum absorbing materials with simultaneous absorption of radar waves, infrared radiation and other multi-band electromagnetic waves has become an important topic in the research and development of wave absorbing materials at present. In order to adapt to multi-climatic environmental conditions, multi-functional materials such as new energy electrode materials with the capabilities of wave absorption, corrosion prevention, self-cleaning, ice and snow resistance and electrocatalysis are developed. Using relevant principles of microwave chemistry, the wave absorbing materials are combined with a catalytic reaction function, which can initiate required chemical reactions by using microwave energy more effectively, thereby achieving conversion between electromagnetic wave energy and chemical energy, etc. The era of a series of dual-functional and even multi-functional wave absorbing materials has gradually opened, which has become an important direction for the research of wave absorbing materials in the future.

Electromagnetic interference and electromagnetic radiation pollution have increasingly become important problems that plague the human health and life, while electromagnetic information leakage and electromagnetic radiation from military electronic equipment may also become clues for enemy detection, and bring threats to military targets and national defense security. Therefore, the research and development of wave absorbing and shielding materials for high-efficiency broadband electromagnetic waves is of great significance.

Ideal wave absorbing materials should have the so-called “thin, light, wide and strong” four key points of light weight, thin thickness, wide absorption frequency band and strong wave absorption capability, and have good mechanical properties, environmental adaptability and chemical stability, as well as excellent comprehensive properties such as convenience in processing and use. Countries around the world are working to develop novel wave absorbing materials to meet this demand.

Two-dimensional nano materials such as MXene, g-C₃N₄, graphene and their oxides have high specific surface areas, high electrical conductivity, high thermal conductivity, high dielectric constant and mechanical properties, and are the research hotspots for the development of novel materials.

A high-entropy alloy sulfide system of a single solid solution is formed by mixing of five or more elements at an equal or near-equal molar ratio. Due to the multiple effects of severe lattice transformation, slow atomic synergistic diffusion, high mixed entropy, “cocktail” and etc. in an atomic structure, high-entropy alloy sulfides prepared by means of mechanical alloying, powder metallurgy, wet chemistry and other methods show a wide range of application prospects in the fields of photocatalysis, electrocatalysis, new energy electrode materials and excellent degradation of pollutants in water.

However, at present, sulfur atoms are depleted when a high-entropy transition metal sulfide-two-dimensional nano composite material is prepared by a simple solid-phase sintering method. When a solid-phase sintering temperature reaches more than 800° C., N and S atoms basically disappear completely. At the same time, nano high-entropy alloy sulfides are used as electromagnetic shielding materials, and their electromagnetic wave absorption capabilities are obviously insufficient.

### SUMMARY OF THE INVENTION

In order to overcome the existing technical defects, an object of the present application is to provide a high-entropy alloy sulfide/two-dimensional nano composite material, a preparation method therefor, and an application thereof. The high-entropy alloy sulfide/two-dimensional nano composite material prepared by the present application has more effective electromagnetic wave absorption capability and stability.

In order to solve the above technical problems, the present application provides the following technical solutions.

In a first aspect, a preparation method for a high-entropy alloy sulfide/two-dimensional nano composite material is provided. The composite material includes the following steps:
S1: dissolving zinc acetate, copper acetate, ferric acetate, nickel acetate, and cadmium acetate in an organic solvent, then adding a sulfide and a two-dimensional nano material, dispersing and uniformly mixing to obtain a mixed solution; and
S2: heating the mixed solution obtained in step S1 to 140-220° C. for reaction, cooling to room temperature after heat preservation, performing centrifugal separation at room temperature, and washing and drying the centrifuged product to obtain the high-entropy alloy sulfide/two-dimensional nano composite material, wherein the zinc acetate, the copper acetate, the ferric acetate, the nickel acetate and the cadmium acetate are added at an equal or approximately equal molar ratio; the sulfide is selected from one of thiourea, aminothiourea and thioacetamide; and the two-dimensional nano material is selected from one of Ti₃C₂ MXene, g-C₃N₄, graphene and their oxides.

It should be understood that the zinc acetate, the copper acetate, the ferric acetate, the nickel acetate and the cadmium acetate are used as precursor compounds to prepare a high-entropy alloy in the present application, and therefore, the zinc acetate, the copper acetate, the ferric acetate, the nickel acetate and the cadmium acetate are added at an equal or approximately equal molar ratio.

In the present application, the preparation method may be used to obtain the high-entropy alloy sulfide-two-dimensional nano composite material in situ in one step.

Further, in step S1, the organic solvent is one or a combination of more of ethylenediamine, triethanolamine, phenylacetonitrile, and acetonitrile.

Further, in step S1, the content of a two-dimensional nano material in the mixed solution is 1 to 15%, based on a total weight of the mixed solution.

Further, in step S1, a molar ratio of the zinc acetate, the copper acetate, the ferric acetate, the nickel acetate or the cadmium acetate to the sulfide is 1:(2-5).

Further, in step S1, the dispersing and mixing process may adopt ultrasonic mixing; and preferably, the dispersing and mixing time is 30-60 min.

Specifically, programmed heating is preferably used for a heating operation in the present application.

Further, in step S2, the heating refers to the programmed heating to 140-220° C. at a rate of 1-5° C./min.

Preferably, the heating refers to the programmed heating to 140-220° C. at a rate of 1-3° C./min.

Further, in step S2, the heat preservation time is 12-24 h.

Further, the washing is carried out with deionized water and/or absolute ethanol.

Preferably, the washing is repeated for a plurality of times with deionized water and absolute ethanol.

Further, in step S2, the drying temperature is 80-100° C.

Preferably, in step S2, drying is performed in a vacuum drying oven at a temperature of 90° C.

In a second aspect, a high-entropy alloy sulfide/two-dimensional nano composite material is provided. The high-entropy alloy sulfide/two-dimensional nano composite material is prepared by the preparation method as described in the first aspect.

In a third aspect, an application of the high-entropy alloy sulfides/two-dimensional nano composite material as described in the second aspect in the preparation of an electromagnetic wave shielding material, a new energy electrode material and an electrocatalytic material is provided.

Compared with the prior art, the present application has the following technical effects.
1. According to the preparation method provided by the present application, S atoms in the high-entropy alloy sulfide/two-dimensional nano composite material are not lost.
2. In the present application, a stable high-entropy alloy sulfide is used instead of a single metal or binary metal alloy sulfide, so that the oxidation resistance and electromagnetic wave shielding performance of the prepared composite material are enhanced.
3. Compared with a single non-noble-metal high-entropy alloy, the high-entropy alloy sulfide/two-dimensional nano composite material provided by the present application has significantly improved shielding performance for electromagnetic waves, as well as significantly improved stability.

The additional aspects and advantages of the present application will be partially given in the following description, and some will become obvious from the following description, or be learned through the practice of the present application.

### BRIEF DESCRIPTION OF THE DRAWINGS

The accompanying drawings described here are used to provide a further understanding of the present application, and constitute a part of the present application, but do not constitute an improper limitation of the present application. In drawings:

FIG. 1 is an XRD pattern of a nano high-entropy alloy sulfide at different reaction temperatures in Example 3 of the present application;

FIG. 2 is an XRD pattern of the nano high-entropy alloy sulfide in Example 3 of the present application;

FIG. 3 is an XRD pattern of a nano graphene oxide-high-entropy alloy sulfide composite material at different reaction temperatures in Example 2 of the present application;

FIG. 4 is an XRD pattern of the nano graphene oxide-high-entropy alloy sulfide composite material in Example 2 of the present application;

FIG. 5 is a two-dimensional pattern of an electromagnetic wave absorption capability of the nano high-entropy alloy sulfide in Example 3 of the present application;

FIG. 6 is a two-dimensional pattern of an electromagnetic wave absorption capability of the nano graphene oxide-high-entropy alloy sulfide composite material in Example 2 of the present application;

FIG. 7 is a three-dimensional pattern of an electromagnetic wave absorption capability of the nano graphene oxide-high-entropy alloy sulfide composite material in Example 2 of the present application;

FIG. 8 is a cyclic voltammetry diagram of Example 1 of the present application; and

FIG. 9 is a cyclic voltammetry diagram of Example 4 of the present application.

### DETAILED DESCRIPTION OF THE INVENTION

In order to understand the technical content of the present application more fully, the present application will be further introduced and explained below in conjunction with the accompanying drawings and specific examples: obviously, the described examples are only part of the examples, not all of the examples, of the present application. Based on the examples of the present application, all other examples derived by a person skilled in the art without creative efforts shall fall within the protection scope of the present application.

For a person skilled in the art, the features, beneficial effects, and advantages of the present application will become apparent by reading the content disclosed in this specification.

Unless otherwise indicated, all percentages, fractions and ratios are calculated on the basis of a total weight of a composition of the present application. The term “weight content” herein may be represented by a symbol “%”.

In the following examples, an instrument used in an electromagnetic wave shielding experiment is: Agilent PNA-N5244A.

The reagents or instruments used in the following examples, which are not marked with manufactures, are regarded as conventional products that are commercially available.

In the following examples, a molar ratio of the zinc acetate, the copper acetate, the ferric acetate, the nickel acetate or the cadmium acetate to the sulfide is 1:2-5. The addition amount of the sulfide may be adjusted appropriately to ensure that the zinc acetate, the copper acetate, the ferric acetate, the nickel acetate and the cadmium acetate may fully react with the sulfide.

In the following examples, the zinc acetate, the copper acetate, the ferric acetate, the nickel acetate and the cadmium acetate are commercially available metal acetate compounds.

### Example 1

The present example provides a nano Ti₃C₂-high-entropy alloy sulfide composite material. Specifically, the nano Ti₃C₂-high-entropy alloy sulfide composite material is a few-layer porous composite material. A preparation method for the composite material includes the following steps:

1) Preparation of Ti₃C₂ MXene

1 g of commercial Ti₃AlC₂ was added to 300 mL of hydrofluoric acid (HF, 100 mL, 40 wt %), stirred at room temperature in a reaction flask for 72 h, then centrifugally separated at high speed (10000 rps), and washed with deionized water to obtain a two-dimensional nano material Ti₃C₂ MXene, and the Ti₃C₂ MXene was freeze-dried for 48 h for later use;

### 2) Preparation of Nano High-Entropy Alloy Sulfide

cadmium acetate tetrahydrate, zinc acetate hydrate, copper acetate hydrate, nickel acetate hexahydrate and ferric acetate tetrahydrate which were taken equimolarly were dissolved in 50 mL of deionized water, mixed and stirred for 30 min to obtain a mixture; thioacetamide (25 mmol) and ethylenediamine (10 mL) were added to the mixture and stirred for 30 min; then, the mixture was transferred to a 100 mL reaction kettle, slowly heated to 200° C. for the reaction, maintained for 24 h, naturally cooled to room temperature, and centrifugally separated at high speed (10000 rps); and the product was washed with deionized water for three times and dried overnight in a vacuum drying oven to obtain a nano high-entropy alloy sulfide; and

3) Preparation of Nano Ti₃C₂ High-Entropy Alloy Sulfide Composite Material

1 g of the product in step 2) was taken and dissolved in deoxygenated deionized water, and then 0.1 g of the product Ti₃C₂ in step 1) was taken and dissolved in 10 mL of deionized water, and stirred for 2 h under an argon condition; the two solutions were transferred to a 100 mL high-pressure reactor, reacted by programmed heating to 200° C. at a rate of 3° C./min, heat-preserved for 24 h, naturally cooled to room temperature, and centrifugally separated at high speed (10000 rps); and the product was washed with deionized water for three times and dried at 60° C. overnight in the vacuum drying oven to obtain the nano Ti₃C₂-high-entropy alloy sulfide composite material.

Specifically, a series of nano Ti₃C₂-high-entropy alloy sulfide composite materials may be obtained by adding different amounts of Ti₃C₂ to the reaction system.

### Example 2

The present example provides a nano graphene oxide-high-entropy alloy sulfide composite material. Specifically, the nano graphene oxide-high-entropy alloy sulfide composite material is a few-layer porous composite material. A preparation method for the composite material includes the following steps:
cadmium acetate tetrahydrate, zinc acetate hydrate, copper acetate hydrate, nickel acetate, ferric acetate and thiourea (30 mmoL) and 900 mg of graphene oxide which were taken at an equal molar ratio were added to 60 mL of ethylenediamine, stirred for 30 min, then transferred to a 100 mL high-pressure reactor, reacted by programmed heating to 200° C. at a rate of 2° C./min, heat-preserved for 24 h, naturally cooled to room temperature, and centrifugally separated at high speed (10000 rps); and the product was washed with deionized water for three times and then with absolute ethanol for three times, and dried at 90° C. overnight in a vacuum drying oven to obtain the nano graphene oxide-high-entropy alloy sulfide composite material.

### Example 3

The present example provides a nano high-entropy alloy sulfide. A preparation method for the nano high-entropy alloy sulfide includes the following steps:
1070 mg of cadmium acetate tetrahydrate, 876 mg of zinc acetate hydrate, 724 mg of copper acetate hydrate, 994 mg of nickel acetate, 932 mg of ferric acetate and 1220 mg of thiourea were added to 60 mL of ethylenediamine, stirred for 30 min, then transferred to a 100 mL high-pressure reactor, heated to 200° C., heat-preserved for 24 h, naturally cooled to room temperature, and centrifugally separated at high speed (10000 rps); and the product was washed with deionized water for three times and then with absolute ethanol for three times, and dried at 90° C. overnight in a vacuum drying oven to obtain the nano high-entropy alloy sulfide.

### Example 4

The present example provides a nano g-C₃N₄-high-entropy alloy sulfide composite material. A preparation method for the nano g-C₃N₄-high-entropy alloy sulfide composite material includes the following steps:

1) Preparation of g-C₃N₄

melamine (2 g) was taken as a precursor, heated at a rate controlled at 10° C./min in a nitrogen atmosphere, maintained at 550° C. for 4 h, cooled at a rate of 10° C./min in the nitrogen atmosphere, and then ground into powder; the product was transferred to a porcelain boat of a tube furnace, heated to 550° C. at a programmed heating rate of 2° C./min, and maintained at 550° C. in a nitrogen atmosphere or nitrogen atmosphere for 4 h to obtain g-C₃N₄; and

2) Preparation of Nano-g-C₃N₄-High-Entropy Metal Sulfide Composite Material

the nano high-entropy alloy sulfide (1 g) of Example 3 was taken and added to 40 mL of ultrapure water; before ultrasonic treatment, a suspension was fully bubbled with argon to eliminate residual oxygen, and then ultrasonically treated in an ice water bath for 8 h; 0.2 g of g-C₃N₄ was taken and dispersed in 20 mL of deionized water and treated ultrasonically for 1 h; the two solutions were merged and transferred to a 100 mL high-pressure reactor, reacted by programmed heating to 200° C. at a rate of 3° C./min, maintained for 24 h, naturally cooled to room temperature, and centrifugally separated at high speed (10000 rps); and the product was washed with deionized water for three times and with absolute ethanol for three times, and then dried at 90° C. overnight in a vacuum drying oven to obtain the nano-g-C₃N₄-high-entropy alloy sulfide composite material.

### Related Performance Tests:

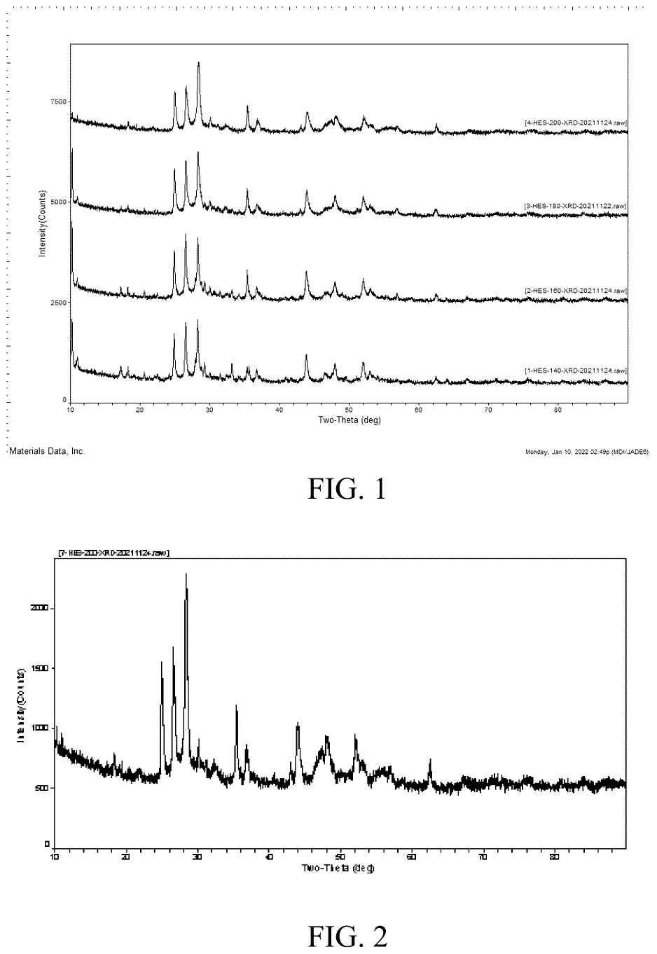

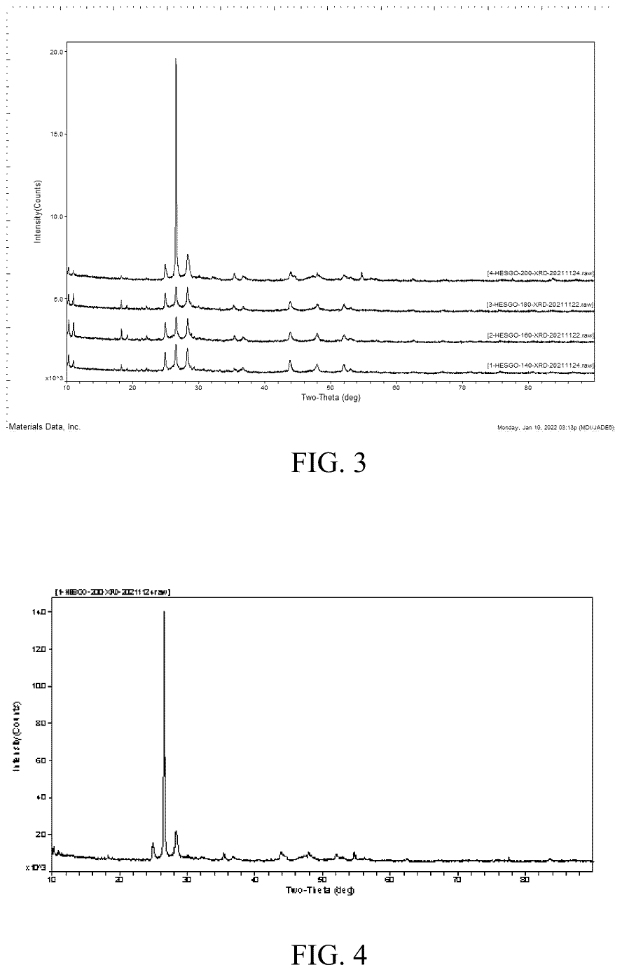

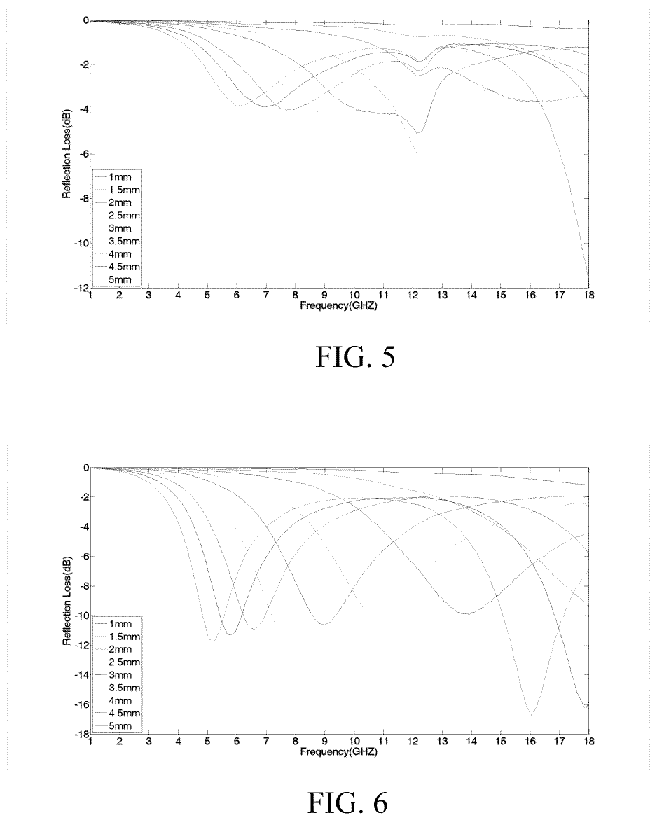

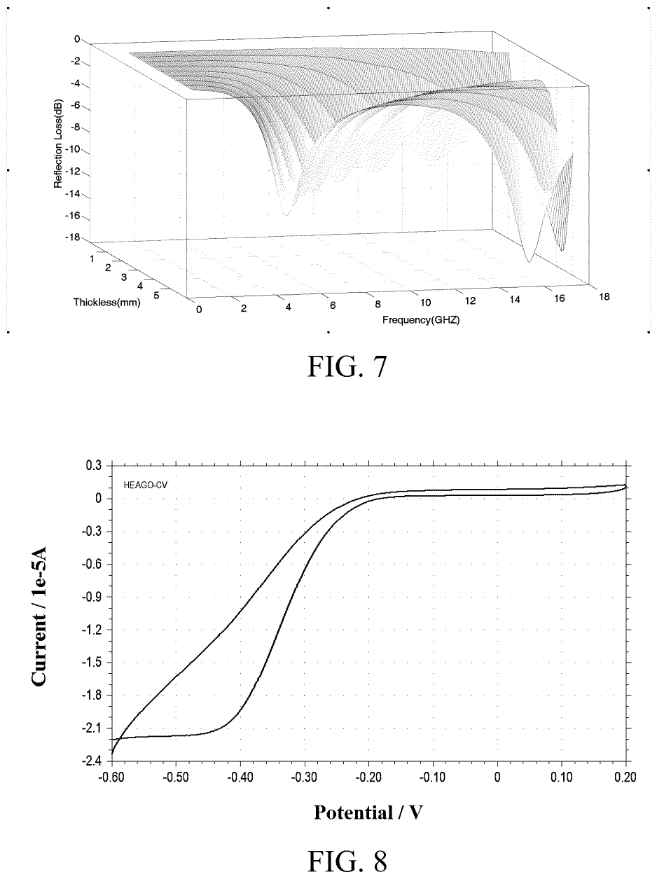

An XRD pattern of the nano high-entropy alloy sulfide in Example 3 was shown in FIG. 1 and FIG. 2; an XRD pattern of the nano graphene oxide-high-entropy alloy sulfide composite material in Example 2 was shown in FIG. 3 and FIG. 4; a two-dimensional diagram of an electromagnetic wave absorption capability of the nano high-entropy alloy sulfide in Example 3 was shown in FIG. 5; a two-dimensional pattern of an electromagnetic wave absorption capability of the nano graphene oxide-high-entropy alloy sulfide composite material in Example 2 was shown in FIG. 6; and a three-dimensional pattern of an electromagnetic wave absorption capability of the nano graphene oxide-high-entropy alloy sulfide composite material in Example 2 was shown in FIG. 7.

Specifically, as shown in FIG. 1 and FIG. 2, the XRD pattern of the nano-high-entropy alloy sulfide in Example 3 disappeared with the increase of reaction temperatures at 10.23°, 11.01°, 17.18°, 20.58°, 22.06°, and 22.49°, indicating a decrease in heterocrystalline phases. It increased with the increase of reaction temperature at 28.25° C., indicating that the heterocrystalline phases disappeared, the number of system phases decreased, and the nano high-entropy alloy sulfide had been formed.

The nano high-entropy alloy sulfide of Example 3 is used for comparison with the nano high-entropy alloy sulfide composite material of Example 2.

As shown in FIG. 3 and FIG. 4, peaks of the nano high-entropy alloy sulfide-graphene composite material of Example 2 at 10.29°, 10.997°, 18.28° and 22.09° disappeared, but did not change at 24.90°, 26.56° and 28.29°. With the increase of the reaction temperature at 26.56°, the heterocrystalline phases decreased, indicating that the nano graphene oxide-high-entropy alloy sulfide was formed by compounding, so S atoms in the prepared high-entropy alloy sulfide two-dimensional nano composite material would not be lost.

By comparing the XRD patterns in FIG. 2 and FIG. 4, there was an XRD peak at 26.56° that could be easily mistaken for graphene oxide.

As shown in the two-dimensional pattern of FIG. 5, the nano high-entropy alloy sulfide of Example 3 had an effect of absorbing electromagnetic waves in bands of 6-18 GHz, but had weak electromagnetic wave absorption capability. Further referring to the two-dimensional pattern of the nano graphene oxide-high-entropy alloy sulfide composite material in FIG. 6 and the three-dimensional pattern of FIG. 7, after the two-dimensional nano material was added, the band of the composite material of Example 2 to absorb electromagnetic waves was expanded to bands of 5-18 GHz and the electromagnetic wave absorption capability was further increased. The electromagnetic wave absorption capability of each band was as follows: 16 GHz, 4.5 mm, −16.71 dB; 18 GHz, 5 mm, −16.18 dB; 5 GHz, 1.5 mm, −9. 45 dB; 6 GHz, 2 mm, −9.92 dB; 7 GHz, 2.5 mm, −10.21 dB; 9 GHz, 3.0 mm, −10.62 dB; 7.5 GHz, 3.5 mm, −10.95 dB; 11 GHz, 4.0 mm, −10.92 dB.

From the above test results, it could be concluded that the reflection loss increased due to a synergistic effect between the dielectric loss and magnetic loss of graphene oxide (two-dimensional nano material) and nano high-entropy alloy sulfide.

In summary, the present application increased the reflection loss of the composite material under the synergistic effect of the magnetic loss and the dielectric loss of the two-dimensional nano material, with the use of the advantages of the nano high-entropy alloy sulfide that is not easy to be oxidized, and resistant to high temperature resistance and friction, etc.

The electrochemical performances of the composite materials prepared in Examples 1 and 4 were tested.

The specific steps were as follows.

### Preparation of Working Electrode:

Firstly, a surface of a glassy carbon electrode was polished with metallographic sandpaper with a particle size of 05 #model, and then polished with alumina polishing powder for 1 h till the mirror surface was smooth, then ultrasonically treated for 30 min, and finally washed with distilled water. 5 g of prepared sample was weighed, added with 50 μL of Nafion membrane solution, 0.5 mL of distilled water and 0.5 mL of ethanol, and stirred ultrasonically for 30 min such that a suspension was evenly dispersed. Then, 25 μL of suspension was added dropwise to the surface of the electrode by using a microsyringe and dried at room temperature.

All electrochemical tests were carried out under a three-electrode system at a temperature of 25° C. and atmospheric pressure. The working electrode was a glassy carbon (GC) electrode (=5 mm) coated with a prepared catalyst (nano Ti₃C₂-high-entropy alloy sulfide), a counter electrode was a Pt sheet electrode (=5 mm), a reference electrode was a saturated calomel electrode (SCE), and an electrolyte was a 0.1 mol L⁻¹ KOH solution. Oxygen was introduced to the solution for half an hour before all electrochemical tests, such that the oxygen was saturated in the solution for subsequent electrochemical tests.

The number of electrons transferred per oxygen molecule in an oxygen reduction reaction could be calculated using the following Koutecky-Levich equation:

$$\frac{1}{j} = \frac{1}{jk} + \frac{1}{B {ω}^{1 / 2}} \qquad ( 2.1 )$$

$$B = 0.2 {nF ( {D}_{{O}_{2}} )}^{2 / 3} {v}^{- 1 / 6} {C}_{{O}_{2}} \qquad ( 2.2 )$$

According to Formula 2.2, it was derived: B=3.09×10⁻⁵ n, and B was substituted into Formula 2.1 after @ was obtained, and then the number of electrons transferred at a certain potential was calculated.

In CV curves of Example 1 and Example 4 in an O₂-saturated 0.1 mol L⁻¹ KOH solution, a sweep velocity was 20 mVs⁻¹; and the number of electrons transferred per oxygen molecule in the oxygen reduction reaction catalyzed an oxygen reduction process with both two-electron and four-electron pathways.

### Test Results and Analysis

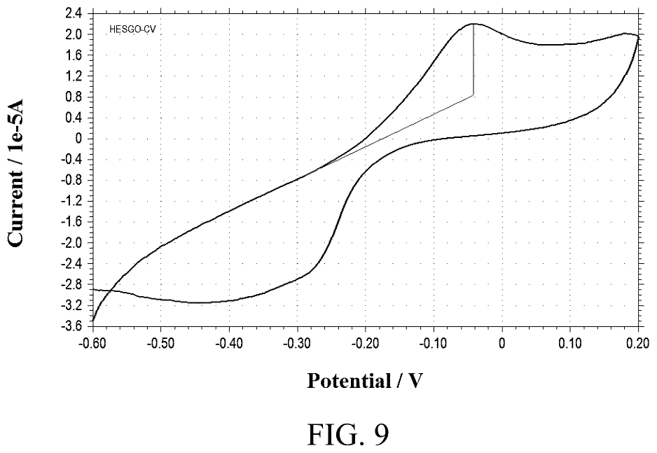

The electrochemical test results of the composite materials of Example 1 and Example 4 were shown in FIG. 8 and FIG. 9 respectively. According to the test results of FIG. 8 and FIG. 9, currents of the composite materials of Example 1 and Example 4 all had peak currents with the change of voltage, indicating that the composite materials of Example 1 and Example 4 would undergo an electrochemical oxidation or reduction reaction under this potential, indicating that they had certain electrode activities, and thus used as new energy electrode materials.

It is of great significance for the application of the high-entropy alloy sulfide two-dimensional nano composite material in civil applications such as protection against electromagnetic wave radiation, as well as related fields in the development of military stealth materials and new energy electrode materials, etc. The electromagnetic wave shielding material could achieve a design goal of functional and structural integration on the basis of weight reduction and efficiency increase, which could not only promote the development of national defense and military stealth materials, but also played an important role in the protection of electromagnetic wave radiation and other civilian aspects.

The technical solutions provided by the examples of the present application have been introduced in detail. Specific examples are used herein to illustrate the principles and embodiments of the present application. The description of the above examples is only used to help the understanding of the principles of the examples of the present application. At the same time, for a person skill in the art, according to the examples of the present application, there will be changes in the specific embodiments and the scope of application. In summary, the content of the present specification should not be construed as a limitation of the present application.

1. A preparation method for a high-entropy alloy sulfide/two-dimensional nano composite material, comprising the following steps:
S1: dissolving zinc acetate, copper acetate, ferric acetate, nickel acetate, and cadmium acetate in an organic solvent, then adding a sulfide and a two-dimensional nano material, dispersing and uniformly mixing to obtain a mixed solution; and
S2: heating the mixed solution obtained in step S1 to 140-220° C. for reaction, cooling to room temperature after heat preservation, performing centrifugal separation at room temperature, and washing and drying the centrifuged product to obtain the high-entropy alloy sulfide/two-dimensional nano composite material, wherein
the zinc acetate, the copper acetate, the ferric acetate, the nickel acetate and the cadmium acetate are added at an equal or approximately equal molar ratio; the sulfide is selected from one of thiourea, aminothiourea and thioacetamide; and the two-dimensional nano material is selected from one of Ti₃C₂ MXene, g-C₃N₄, graphene and their oxides.

2. The preparation method according to claim 1, wherein in step S1, the organic solvent is one or a combination of more of ethylenediamine, triethanolamine, phenylacetonitrile, and acetonitrile.

3. The preparation method according to claim 1, wherein in step S1, the content of a two-dimensional nano material in the mixed solution is 1-15%, based on a total weight of the mixed solution.

4. The preparation method according to claim 1, wherein in step S1, a molar ratio of the zinc acetate, the copper acetate, the ferric acetate, the nickel acetate or the cadmium acetate to the sulfide is 1:(2-5).

5. The preparation method according to claim 1, wherein in step S2, the heating refers to programmed heating to 140-220° C. at a rate of 1-5° C./min.

6. The preparation method according to claim 1, wherein in step S2, the heat preservation time is 12-24 h.

7. The preparation method according to claim 1, wherein in step S2, the washing is carried out with deionized water and/or absolute ethanol.

8. The preparation method according to claim 1, wherein in step S2, the drying temperature is 80-100° C.

9. (canceled)

10. (canceled)

11. A high-entropy alloy sulfide/two-dimensional nano composite material, wherein the high-entropy alloy sulfide/two-dimensional nano composite material is prepared by the preparation method according to claim 1.

12. A high-entropy alloy sulfide/two-dimensional nano composite material, wherein the high-entropy alloy sulfide/two-dimensional nano composite material is prepared by the preparation method according to claim 2.

13. A high-entropy alloy sulfide/two-dimensional nano composite material, wherein the high-entropy alloy sulfide/two-dimensional nano composite material is prepared by the preparation method according to claim 3.

14. A high-entropy alloy sulfide/two-dimensional nano composite material, wherein the high-entropy alloy sulfide/two-dimensional nano composite material is prepared by the preparation method according to claim 4.

15. A high-entropy alloy sulfide/two-dimensional nano composite material, wherein the high-entropy alloy sulfide/two-dimensional nano composite material is prepared by the preparation method according to claim 5.

16. A high-entropy alloy sulfide/two-dimensional nano composite material, wherein the high-entropy alloy sulfide/two-dimensional nano composite material is prepared by the preparation method according to claim 6.

17. A high-entropy alloy sulfide/two-dimensional nano composite material, wherein the high-entropy alloy sulfide/two-dimensional nano composite material is prepared by the preparation method according to claim 7.

18. A high-entropy alloy sulfide/two-dimensional nano composite material, wherein the high-entropy alloy sulfide/two-dimensional nano composite material is prepared by the preparation method according to claim 8.
